(19) United States
(12) Patent Application Publication
(10) Pub. No.: US 2008/0099814 A1
(43) Pub. Date: May 1, 2008

(54) INTEGRATED CIRCUIT AND METHOD FOR PRODUCTION

(75) Inventors: Ulrike Gruening-von Schwerin, Muenchen (DE); Till Schloesser, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/554,335

(22) Filed: Oct. 30, 2006

(51) Int. Cl. H01L 27/10; H01L 21/336; H01L 21/82

(52) U.S. Cl. 257/302; 438/270; 257/E27.084; 438/128; 257/E27.07; 257/E21.602

(57) ABSTRACT

An array of vertical transistor cells formed in a substrate for selecting one of a plurality of memory cells by selecting a word line and a bit line is disclosed. In one embodiment, for minimizing the area of a cell and reducing complexity in production a plurality of parallel insulating trenches filled with an insulating material and a plurality of perpendicular gate electrode trenches is formed, the gate electrode trenches filled with a suitable gate electrode material disrupted by the insulating material thus forming separate gate electrodes arranged below the reference plane. The insulating trenches and the gate electrode trenches form distinct active areas of transistors in the substrate, wherein two gate electrodes located at opposing sidewalls of an active area form a double gate electrode of a transistor, and wherein a plurality of gate electrodes is coupled to a word line running perpendicular to the gate electrode trenches and above the reference plane.

### BACKGROUND

The invention relates to an array of vertical transistors formed in a substrate to select one of a plurality of resistively switching memory cells, a memory component having an array of vertical transistors, an electronic system, and a method for forming an array of vertical transistors.

In a “resistive” or “resistively switching” memory cell, an “active” or “switching active” material, which usually is positioned between two suitable electrodes, i.e. an anode and a cathode, can be switched between a conductive and a less conductive state by an appropriate switching process. The conductive state can be assigned a logic one and the less conductive state can be assigned a logic zero, or vice versa.

For phase change memories (PCRAMs), for instance, an appropriate chalcogenide compound, for example Ge—Sb—Te (GST) or an In—Sb—Te compound, may be used as a “switching active” material that is positioned between two corresponding electrodes. This “switching active” material can be switched between an amorphous and a crystalline state. The amorphous state is a relatively weakly conducting state, which accordingly can be assigned a logic zero. The crystalline state, i.e. a relatively strongly conductive state, accordingly can be assigned a logic one.

To achieve a change from the amorphous, i.e. a relatively weakly conductive state of the switching active material, to a crystalline, i.e. a relatively strongly conductive state, the material has to be heated. For this purpose a heating current pulse is sent through the material, which heats the switching active material beyond its crystallization temperature thus lowering its resistance. In this way the value of a memory cell can be set to a first logic state.

Vice versa, the switching material can be heated by applying a relatively high current to the cell which causes the switching active material to melt and by a subsequent “quench cooling” the material can brought into an amorphous, i.e. relatively weakly conductive state, which may be assigned a second logic state.

Various concepts have been proposed for PCRAM cells, for example by S. J. Ahn, “Highly Manufacturable High Density Phase Change Memory of 64 MB and Beyond”, IEDM 2004, H. Horii et al “A novel cell technology using N-doped GeSbTe films for phase change RAM”, VLSI, 2003, Y. N. Hwang et al “Full integration and reliability evaluation of phase-change RAM based on 0.24 um-CMOS technologies”, VLSI, 2003, S. Lai et al “OUM—a 180 nm non-volatile memory cell element technology for stand alone and embedded applications”, IEDM 2001, or Y. H. Ha et al “An edge contact cell type cell for phase change RAM featuring very low power consumption”, VLSI, 2003.

The proposed memory cells in general use planar array transistors or transistors having the source/drain contacts in the same horizontal plane even though their channels are vertical, or otherwise located in a different plane, for example FinFETs. Such a design makes it difficult to shrink the cell size for geometrical reasons, because the size of a cell includes the area needed for the transistor to select the cell.

Further, DRAM memory cells are known having an array of vertical transistor cells formed in a substrate having lower source/drain regions connected to a common connection plate. Upper source/drain regions of the transistor cells impart a contact connection to a storage capacitor. The array of transistor cells is formed by wordline trenches, and by isolation trenches (STI) running perpendicular to the wordline trenches. The wordlines in the trenches form gate electrodes of the transistors.

To be cost competitive a small cell size is required allowing a high density of memory cells in a memory cell array.

For these or other reasons, there is a need for the present invention.

### SUMMARY

One embodiment provides an integrated circuit having an array of vertical transistors formed in a substrate to select one of a plurality of resistively switching memory cells by selecting a word line and a bit line, the surface of the substrate defining a horizontal reference plane, having a plurality of parallel insulating trenches filled with an insulating material and a plurality of perpendicular gate electrode trenches filled with a gate electrode material, each perpendicular gate electrode trench of the plurality of perpendicular gate electrode trenches constructed between two consecutive parallel insulating trenches to form a plurality of gate electrodes arranged below the reference plane, the insulating trenches and the gate electrode trenches forming distinct active areas of transistors of the array of vertical transistors in the substrate, wherein two gate electrodes located at opposing sidewalls of an active area form a double gate electrode of a transistor of the array of vertical transistors, and wherein the plurality of gate electrodes are coupled to a word line running perpendicular to the plurality of perpendicular gate electrode trenches and above the reference plane.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic circuit diagram of two memory cells representing an array of several memory cells.

FIG. 2 illustrates a schematic top-down view onto a cutout of a layout of an array of memory cells.

FIG. 3a illustrates a top-down view on an array of transistors in an early processing stage.

FIGS. 3b, 3c illustrate a cross-section through a transistor at the processing stage of FIG. 3a.

FIGS. 4a-4c illustrate the views as described with reference to FIG. 3 at a later processing stage.

FIG. 5 illustrates a top-down view as in FIG. 4a after having performed additional processing steps.

FIG. 6a illustrates a cross-section through a transistor in bit line direction.

FIG. 6b illustrates a cross section in bit line direction through a gate electrode.

FIG. 6c illustrates a cross section in word line direction through two active areas of adjacent transistors.

FIG. 6d illustrates a cross section in word line direction through two gate electrodes.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment provides an integrated circuit having an array of vertical transistors formed in a substrate to select one of a plurality of resistively switching memory cells by selecting a word line and a bit line, the surface of the substrate defining a horizontal reference plane, having a plurality of parallel insulating trenches filled with an insulating material and a plurality of perpendicular gate electrode trenches filled with a gate electrode material, each perpendicular gate electrode trench of the plurality of perpendicular gate electrode trenches constructed between two consecutive parallel insulating trenches to form a plurality of gate electrodes arranged below the reference plane, the insulating trenches and the gate electrode trenches forming distinct active areas of transistors of the array of vertical transistors in the substrate, wherein two gate electrodes located at opposing sidewalls of an active area form a double gate electrode of a transistor of the array of vertical transistors, and wherein the plurality of gate electrodes are coupled to a word line running perpendicular to the plurality of perpendicular gate electrode trenches and above the reference plane.

Furthermore the invention is directed at integrated circuit having an array of vertical transistors formed in a substrate to select one of a plurality of resistively switching memory cells by selecting a word line and a bit line, the surface of the substrate defining a horizontal reference plane, having a ground plate electrode in the substrate; a plurality of parallel insulating trenches extending into the ground plate electrode and filled with an insulating material; and a plurality of gate electrode trenches extending into the ground plate electrode and being perpendicular to the insulating trenches, the gate electrode trenches filled with a gate electrode material disrupted by the insulating material forming separate gate electrodes arranged below the reference plane, the insulating trenches and the gate electrode trenches forming distinct active areas of transistors emerging from the substrate and coupled to the ground plate electrode, wherein two gate electrodes located at opposing sidewalls of an active area form a double gate electrode of a transistor, and wherein a plurality of gate electrodes are coupled to a word line running perpendicular to the gate electrode trenches and above the reference plane.

Also a method of forming an integrated circuit having an array of transistors in a substrate for selecting one of a plurality of resistively switching memory cells, including the following method processes:

forming a ground plate electrode in the substrate; forming a plurality of parallel insulating trenches in the substrate; forming a plurality of gate electrode trenches, the gate electrode trenches being perpendicular to the insulating trenches; producing a liner of gate dielectric in the gate electrode trenches and filling the gate electrode trenches with a conducting gate electrode material; depositing a three layer stack of gate electrode material, word line material and insulating material and subsequently etching the three layer stack to form word lines running perpendicular to the gate electrode trenches, wherein the word lines are at least partially located vertically above active areas of transistors of the array of transistors.

According to another aspect the invention is directed at a method of forming an integrated circuit having an array of transistors in a substrate for selecting one of a plurality of resistively switching memory cells, the surface of the substrate defining a horizontal reference plane, including the following method processes:

forming a ground plate electrode in the substrate by deeply implanting N+ ions into a layer of the substrate material; forming a plurality of parallel insulating trenches in the substrate by etching and filling stripes in the substrate; forming a plurality of gate electrode trenches, the gate electrode trenches being perpendicular to the insulating trenches, wherein the etching is selective to the insulation material of the insulating trenches, the insulating trenches and the gate electrode trenches thus producing active areas of transistors; producing a liner of gate dielectric in the gate electrode trenches and filling the gate electrode trenches with a conducting gate electrode material; depositing a three layer stack of gate electrode material, word line material and insulating material and subsequently etching the three-layer stack to form a word lines running perpendicular to the gate electrode trenches, the gate electrodes being coupled to word lines by the gate electrode material, wherein the word lines are at least partially located vertically above the active areas and wherein the etching extends into the gate electrode trenches; producing a galvanically insulating layer at the sidewalls of the three-layer stack and in the gaps of the gate electrode trenches; depositing a liner of insulating material and filling gaps between word lines with an insulating material; forming contacts on the active areas to couple for providing a contact to a volume of resistively switching material by etching holes baring at least partially the top surface of the active areas and by filling these holes with a suitable conducting material; forming volumes of resistively switching material coupled to the contacts and forming bit lines coupled to the volumes of resistively switching material.

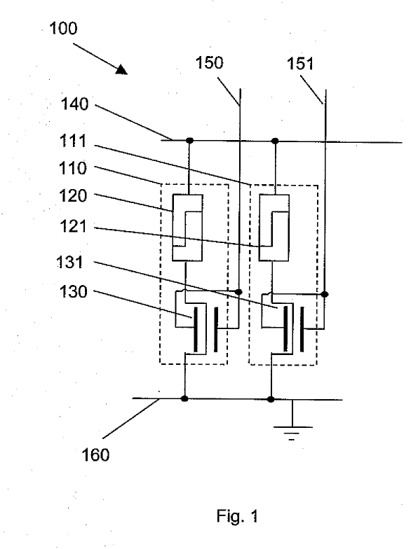

FIG. 1 illustrates an electrical circuit 100. A first and a second memory cell, each surrounded by a dotted line 110 and 111 respectively, exemplify a plurality of identical memory cells arranged in an array.

Each memory cell 110, 111 includes a memory element 120, 121 and a selection transistor 130, 131. In this drawing and throughout the invention the memory element can be any type of resistively switching memory element, for example a volume of phase change material of a PCRAM memory cell or a volume of suitable material of a conducting bridge CBRAM memory cell or of an MRAM cell.

The memory elements 120, 121 are coupled to a bitline 140 with their one end and to the selection transistor 130, 131 of the corresponding memory cell with their residual end.

As indicated in the drawing the selection transistors 130, 131 are double gate transistors, wherein the two gates of a transistor are arranged on opposing sidewalls of the active area of the transistor. Also the transistors are vertical transistors as will be explicated in the following in more detail, wherein vertical describes that—with the original wafer surface serving as a horizontal reference plane throughout the description—the current flows vertically or in other words the drain is arranged substantially vertically above the active area being in turn substantially vertically arranged above the source of a transistor. The gate electrodes of one transistor are coupled to the same word line that is the gate electrodes of transistor 130 are coupled to a first word line 150 and the gate electrodes of transistor 131 are coupled to a second wordline 151.

Further on the transistors 130, 131 are coupled with their source to a ground line 160 being, as will be explicated in more detail below, a ground plate electrode and which is typically a doped layer in the wafer serving as a ground line for all selection transistors. In this way the ground plate electrode is buried below the surface level of the original wafer. The ground plate electrode may alternatively be another type of conductive layer, including metal silicides and metals, for example. The semiconductor material in which the above-noted transistors are formed may then be deposited, epitaxially regrown, or otherwise formed thereon.

Furthermore it is to be noted that the two memory cells are representative for a plurality of memory cells of a memory device wherein the cells are arranged in an array with a plurality of bit lines and word lines for operating the cells. A plurality of memory cells is coupled to one bitline and a plurality of cells is coupled to one wordline, wherein an individual memory cell is coupled to a pair of a bit line and a word line, so that each cell can be selected by selecting the appropriate bit line and word line.

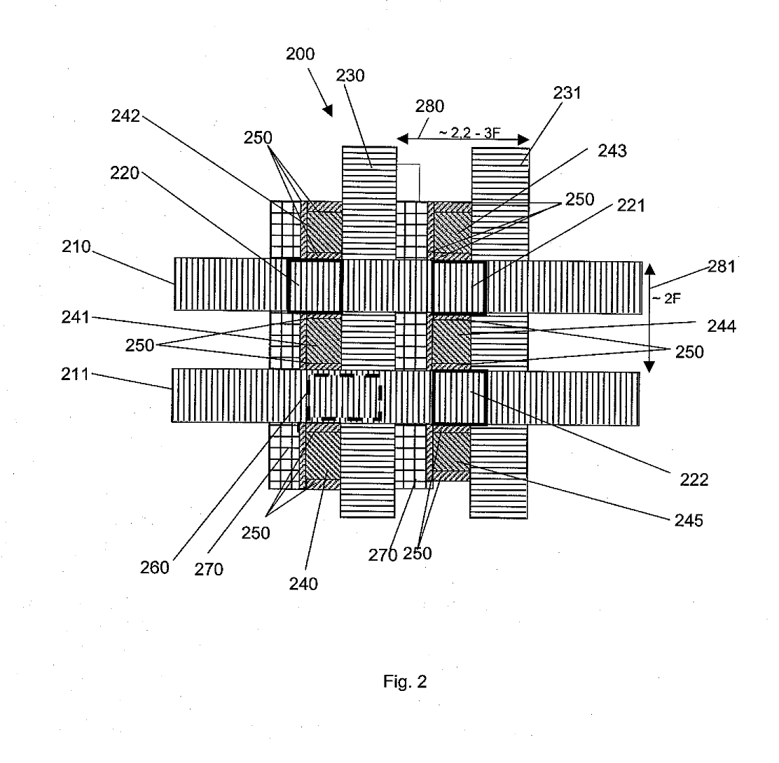

FIG. 2 is a schematic top-down view onto a cutout of a layout of an array 200 of memory cells having the double gate selection transistors.

In this drawing the insulation material separating and insulating elements is partly omitted for reasons of clearness. It is obvious for those skilled in the art that elements, for example bit lines or word lines drawn as separate lines, are embedded in any suitable dielectric to galvanically insulate these against adjacent elements.

Also some elements being essential for resistively switching memory cells, for example such as volumes of resistively switching material, are not illustrated, as they are hidden by other elements located above them. Furthermore the ground plate electrode, onto which the structure is formed, is omitted in this drawing.

A first and a second bit line 210, 211 being the topmost elements in this top-down view are exemplifying a plurality of identical bitlines being positioned adjacent and parallel to these. Each bit line 210, 211 is coupled to a plurality of memory elements of memory cells, which may be for example volumes of phase change material. These memory elements—hidden under the bit lines and thus not visible in this view—are coupled to a bitline 210, 211 via bit line contacts 220, 221, 222 wherein the location of a bit line contact is schematically indicated by a framed quadrangle.

Word lines 230, 231 exemplify a plurality of parallel word lines being perpendicular to and located below the bit lines 210, 211. As mentioned afore each word line is coupled to a plurality of gate electrodes 240-245, that is word line 230 is coupled to gate electrodes 240, 241 and 242 and word line 231 is coupled to gate electrodes 243-245. The gate electrodes 240 and 241 serve as gate electrodes for an active area of a transistor located between these gate electrodes. Thus the gate electrodes are located at opposing sidewalls of the active area of the transistor. The gate electrodes are galvanically insulated by gate oxide 250 against the active area, whose approximate location and shape are indicated by the dotted line 260. As indicated the shape of the active area is an elongated quadrangle sandwiched between gate electrodes 240 and 241 in one direction and by a shallow trench isolation 270 (STI) in the perpendicular direction whereby a comparatively thin layer of gate oxide 250 is located between gate electrodes and active area and STI and active area respectively. Although it is not necessary to have the gate oxide between the active area and the STI, it is typically formed that way.

A transistor having active area 260 furthermore includes gate electrodes 240 and 241, which are coupled to word line 230. The top of the active area 260 is coupled to a memory element—not illustrated-, which in turn is coupled via a bit line contact to bit line 211, wherein the location of the bit line contact is similar to those of 220. The lower end of active area 260 being the source of the transistor is coupled to the ground plate electrode, which is the lowest element and thus invisible in this drawing.

Even though the drawing is not drawn to scale arrow 280 indicates that the periodicity of the word lines is 2,2 to 3 F in the illustrative embodiment and arrow 281 indicates the periodicity of the bit lines being 2 F, wherein F denotes the minimum feature size defined by the manufacturing method used. Consequently the size of the illustrative memory cell is between 4.4 to 6 F2.

Also the approximate size of an active area is defined by the periodicity of the bit—and the word lines. According to current production capabilities a width of 1 F is required for a bit—or a word line, thus the area of an active area is approximately 1.2-2 by 1 F resulting in an area of 1.2-2 F2. Advances in the art of metallurgy and lithography, among others, may change these relative dimensions.

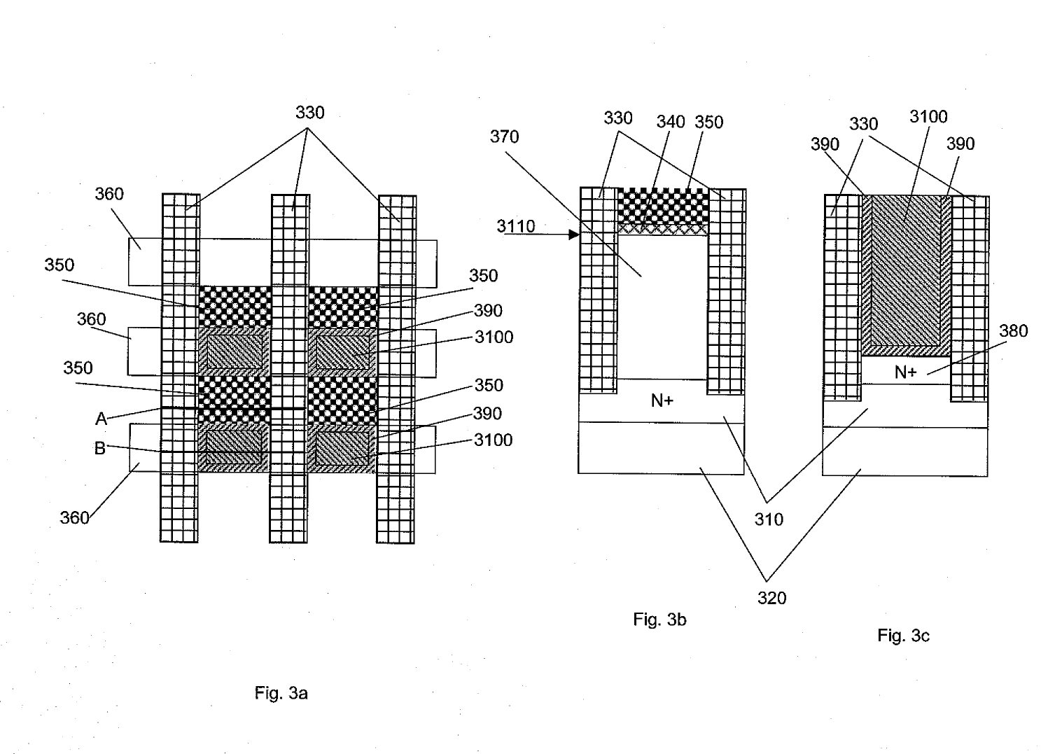

The vertical structure of this arrangement is illustrated in FIG. 3a, which is a top-down view on the array of FIG. 2 in an early processing stage.

FIG. 3a illustrates a top-down view on an array of transistors in an early processing state. FIG. 3b is a cross-sectional view through an active area of a transistor as indicated by line A and FIG. 3c is a cross-sectional view through a gate electrode of a transistor as indicated by line B.

In one of the early method processes a ground plate electrode 310—not illustrated in FIG. 3a—is formed. This can be achieved either by deeply implanting N+ charge carriers into the silicon 320 of the wafer or by performing an implant with a subsequent epitaxial deposition of Si on top. A silicide, metal or other conductive material may then form electrode 310. The Si or other semiconductor material may then be formed by deposition and epitaxial re-growth, or other methods known in the art, or developed hereafter. In this way an N+ doped layer within the silicon 320 of the wafer is produced which will serve as the ground plate electrode 310.

Also a thick pad oxide layer 340 and a SiN layer 350 are deposited on the surface for protection purposes to achieve a better etching.

Insulation trenches are etched into the wafer extending into the ground plate electrode 310. The insulation trenches 330 will serve as shallow insulation trenches (STI) and thus are filled with a suitable insulation material, for example a silicon oxide.

Subsequently gate electrode trenches 360 are etched, wherein the gate electrode trenches are aligned perpendicular to the insulation trenches 330. The etching is furthermore selective to the SiN and silicon oxide so that SiN and SiO in the insulation trenches 330 remain unchanged. As this etching is selective to SiO the trenches are disrupted by the insulation trenches 330, so that holes and at the same time pillars 370 of Si covered by the thick pad oxide layer 340 and the SiN layer 350 are formed. These pillars 370 will serve as active areas of the transistors and optionally can be thinned in order to shape them into an elongated quadrangle. Also a sacrificial oxide layer can be deposited, which is not illustrated in the drawing.

Also an implant of N+ ions can be performed to implant N+ ions into the ground of the holes in case that the holes do not extend into the ground plate electrode 310, wherein the implant is to be limited to the ground area of the holes. Reference numeral 380 indicates an area at a bottom of a hole which has been N+ implanted.

Then, if a sacrificial oxide layer has been deposited before, this is to be removed before an oxide layer is produced on the sidewalls and the ground of such a hole, the layer thus forming a gate oxide 390.

After the gate oxide 390 is formed the holes are filled with a poly silicon to form gate electrodes 3100, wherein the holes can be filled fully or partially—not illustrated-. In case the filling is partially, then the remaining opening can be filled with a dielectric and etched back subsequently.

Also the poly silicon of the gate electrodes optionally can be planarized to the level of the SiN pad 350.

In this way gate electrodes 3100 have been formed, which reach below the original wafer surface level indicated by arrow 3110.

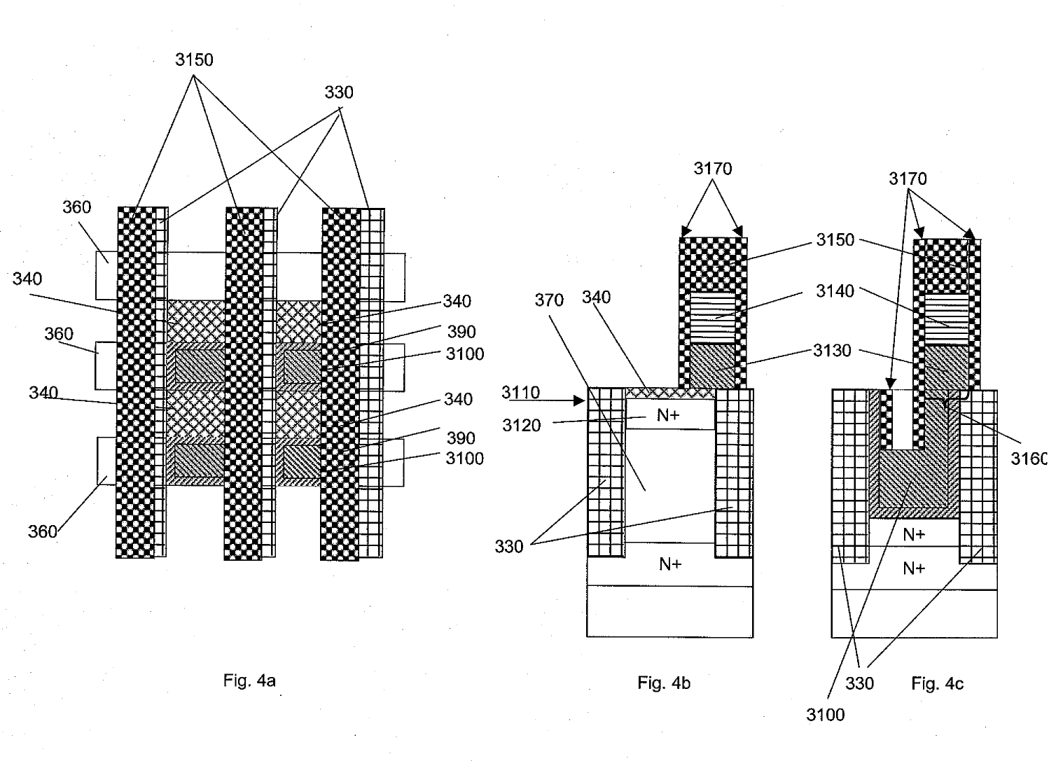

The same views as in FIGS. 3a-3c but at a later processing stage are illustrated in FIGS. 4a-4c. In the drawings same reference signs are used for same items.

In a first optional processing step the insulation of the shallow trench insulation can be etched back.

The SiN layer, denoted by reference numeral 350 in FIG. 3, is removed thus baring the thick pad oxide layer 340 on the active areas 370. As illustrated in the drawing the top of the thick oxide 340 on the active areas is at the level of the STI 330.

At this processing stage well implants can be performed in order to define the semiconductor transitions of the transistors. That is, N+ ions can be implanted into the upper region of the active areas to achieve an N+ doping as indicated by reference sign 3120.

Subsequently a gate conductor stack of three layers—a conventional word line stack—is deposited by at first depositing a layer of a first suitable, conducting material 3130, for example poly silicon in this case as used for the gate electrodes 3100, secondly a layer of a comparatively good conducting material such as a metal 3140, for example tungsten (W) and a layer of a suitable insulating material 3150 such as silicon nitride SiN.

This gate conductor stack is then etched to form a word line 3140 from the metal/tungsten layer. When etching the stack it is to be secured that the overlap of the first layer 3140 provides for a good contact to the gate electrodes 3100 in order to couple the gate electrodes to the metal 3140. That is approximately ⅔ of the area denoted by 3160 overlaps with the surface of gate electrode 3100 in this case. As will be understood any other rate for the overlapping will do as long as a sufficient coupling between the word line 3140 and the gate electrode 3100 is achieved.

The etching of the gate conductor stack is performed so as to etch into gate electrode material 3100. As illustrated in the drawing the material of the gate electrode 3100 has been removed partially, the top surface thus being below the surface level of the original wafer as denoted by arrow 3110.

At this processing stage the gate conductor stack is shaped into lines having open sidewalls thus leaving the wordline 3140 with an open sidewall.

Optionally an angled drain ion implant can be performed to implant N+ ions into the sidewalls of an active area 370 for defining source/drain transitions in the active area of the transistor. This can be useful in case the overetching into the gate electrode material 3100 has damaged the doping of the active area.

Subsequently gate conductor spacers—as denoted by arrows 3170—of insulating material, preferably of the same material as used for the topmost layer of the gate conductor stack is used being in this case silicon nitride, is deposited to cover the sidewalls of the gate conductor stack and the sidewall of the active areas 370 to electrically insulate these. On top of the gate electrodes 3100 the spacers may be thick enough to fill the opening on top of the gate electrodes or, as illustrated in the drawing, the spacers may leave openings on top of the gate electrodes. Consequently a divot fill with the material used for the spacers for filling the gaps is performed, that is depositing silicon nitride and subsequently removing what is too much, may be necessary to fully cap the buried gate electrodes.

FIGS. 4a-4c depict the structure formed by the afore described method processes.

In a subsequent optional method process the thick oxide layer can be removed from the top surface of the active areas and an epitaxial growth of Si—not illustrated—can be performed for enlarging the contact area of the active areas.

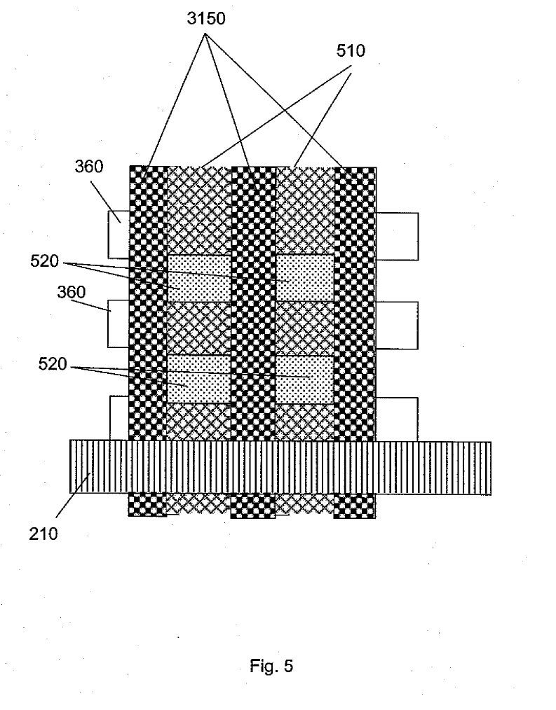

FIG. 5 illustrates a top view on the structure as in previous FIGS. 3a and 4a after having performed further processing steps as explicated hereinafter. Again the same reference numerals are used for same items illustrated in the previous drawings.

It is to be noted that in this schematic drawing reference signs 360 illustrate the position of the gate trenches for demonstration purposes, whereas the actual gate trenches are—as described afore—covered by other layers.

In a further method process a comparatively thin liner of silicon nitride—not illustrated in FIG. 5—is deposited onto the surface of the structure as illustrated in FIG. 4a. Further on a thicker layer of a suitable insulating material 510, for example an oxide such as SiO, is deposited on the chip to fill the remaining gaps, for example between the gate conductor stacks or spacers respectively.

Further on and by using a conventional process the insulating material on top of the active areas is removed by using a conventional lithographic and etching method. Stripes located perpendicular to the word lines and positioned above the active areas are etched wherein the etching is selective to the gate conductors and gate conductor spacers 3150, 3170, thus preserving the wordlines embedded therein. Accordingly holes located above the active areas are etched into the insulating material, which bare the surface of the active areas. At this processing stage the interface contact area to the active areas can be increased by epitaxially growing Si on the surface of the active areas or an implant can be performed to inject N+ ions into the upper region of an active area.

The holes are then filled with a suitable conducting material 520, with a metal, for example tungsten (W), to form a contact to an active area. The conducting material 520 is then planarized to form a planar surface with the surface of gate conductor stacks 3150.

In the afore described method processes a selection transistor has been formed providing a contact, which may serve as a bottom contact of a volume of resistively switching material and on which by using conventional method processes a volume of resistively switching material can be deposited, onto which in turn a bitline 210 can be formed, wherein the bitline 210 couples a plurality of volumes of resistively switching material and is aligned perpendicular to the word lines 3140.

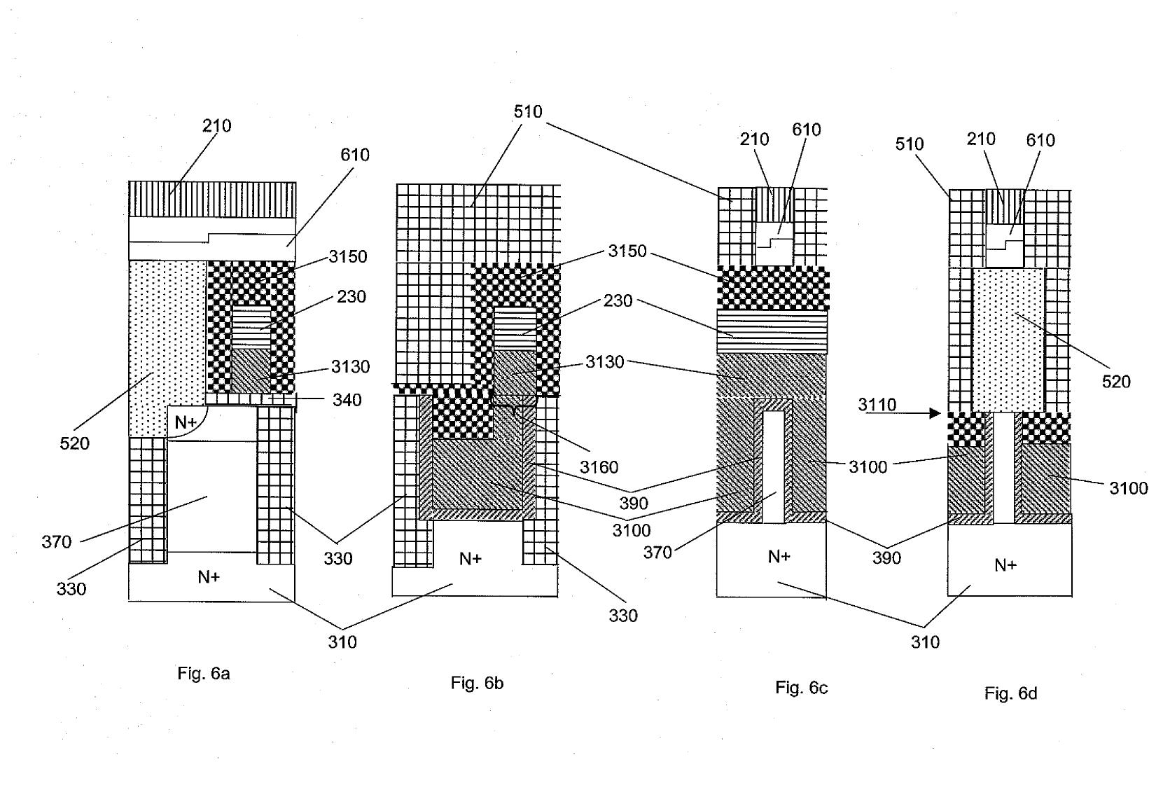

FIGS. 6a to 6d each depict a cross section through the structure of a transistor, wherein FIG. 6a is a cross section in bit line direction through an active area, FIG. 6b is a cross section in bit line direction through a gate electrode, FIG. 6c is a cross section in word line direction through two active areas of two adjacent transistors and FIG. 6d is a cross section in word line direction through two gate electrodes.

FIG. 6a illustrates the active area 370 of a transistor, the lower region being connected to a ground plate electrode 310. The upper region of the active area 370 may have been N+ implanted, either the entire upper region or only in part as indicated by the quarter-circle, which connects to contact 520, which in this case is the bottom contact to a volume of resistively switching material 610, which in turn connects to a bit line 210.

In this view the sidewalls of active area 370 abut against insulation trenches forming a shallow trench isolation (STI) and which in this view run into the paper plane. The top surface of the active area 370 is partly covered by contact 520, to which it connects, and partly covered by residuals of the insulating thick oxide layer 340. The thick oxide layer 340 insulates the gate conductor stack having a line of SiO 3130 and a line of a good conducting material such as a metal forming the wordline 230. The top surface of the gate conductor stack is insulated by a layer of SiN 3150, the sidewalls being insulated by gate conductor spacers.

The ground plate electrode 310, the shallow trench isolation 330 and the gate conductor stack are running into the paper plane and thus are visible in FIG. 6b, which is a parallel cross-section to FIG. 6a but lying in front of or behind as the cut line here runs through a gate electrode 3100. To prevent the gate electrode 3100, which is formed of a conducting material, preferably poly silicon, from contacting an active area—not illustrated here—or the ground plate electrode 310 it is surrounded by a liner 390 of an insulating material such as SiO. Gate electrode 3100 is galvanically coupled to word line 230 via the poly silicon 3130 of the gate conductor stack.

It is to be noted that the lower surface—as indicated by 3160—of the poly silicon 3130 of the gate conductor stack overlaps to the gate electrode 3100 by two thirds of its area. The residual top surface of gate electrode 3100 is covered by the insulating material of the gate conductor spacers, which in turn are covered by a thick layer of insulating material 510.

FIG. 6c is a schematic view of a cross-section in word line direction through an active area of a transistor and a gate conductor stack. As explicated before the gate conductor stack having poly silicon line 3130, the word line 230 and the insulating layer 3150 partly overlap the top surface of an active area 370 of a transistor. The cut line in this drawing crosses the overlapping area.

An active area 370 emerges from ground plate electrode 310. A first and a second gate electrode 3100 are located at the left and right sidewall of the active area 370, insulated by a gate dielectric or gate oxide 390, the two gate electrodes thus forming a dual or double gate for the transistor. The gate electrodes are galvanically coupled by the poly silicon line 3130 and wordline 230.

It is to be noted that both gate electrodes not only serve as gate electrodes for the active area 370 visible in this drawing. Each gate electrode furthermore serves as a gate electrode for another adjacent active area. That is, the gate electrode on the left hand side of active area 370 serves as a gate electrode for the visible active area 370 and also as gate electrode for an active area adjacent to the left side of the gate electrode. Similarly the gate electrode on the right hand side of active area 370 also serves as gate electrode for the next adjacent active area to the right hand side. In this way a plurality of gate electrodes 3100 is coupled to a single word line 230, whereby two gate electrodes form a double gate electrode for one transistor.

Although the drawings are not drawn to scale it is to be noted that the bottom surface of the active area 370 is not a square. When comparing the shapes of an active area 370 of FIG. 6a to that in FIG. 6c it is clear that the shape of the bottom surface of an active area 370 is an elongated quadrangle with the length in word line direction being smaller than the length in bit line direction.

A parallel cross-section through a transistor is illustrated in FIG. 6d, wherein the cut line runs through the contact 520 coupling the active area 370 to a volume of switching active material 610, which in turn is galvanically coupled to a bitline 210. An active area 370 emerges from ground plate electrode 310 and is galvanically coupled to contact 520, which may serve as a bottom contact to the volume of switching active material 610. On the left and right sidewall of active area 370 a gate electrode 3100 is located being insulated from the active area by a gate dielectric 390.

The surface level of the original wafer is denoted by arrow 3110. As can be seen from the drawing the top surface of the gate electrodes is located below the surface level 3110 of the original wafer, so that the gate electrodes are buried in this way.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising an array of vertical transistors formed in a substrate to select one of a plurality of resistively switching memory cells by selecting a word line and a bit line, the original surface of the substrate defining a horizontal reference plane, comprising:
a plurality of parallel insulating trenches filled with an insulating material; and
a plurality of perpendicular gate electrode trenches filled with a gate electrode material, each perpendicular gate electrode trench of the plurality of perpendicular gate electrode trenches constructed between two consecutive parallel insulating trenches to form a plurality of gate electrodes arranged below the reference plane;
the insulating trenches and the gate electrode trenches forming distinct active areas of transistors of the array of vertical transistors in the substrate, wherein two gate electrodes located at opposing sidewalls of an active area form a double gate electrode of a transistor of the array of vertical transistors; and
wherein the plurality of gate electrodes are coupled to a word line running perpendicular to the plurality of perpendicular gate electrode trenches and above the reference plane.

2. The integrated circuit of claim 1, wherein a resistively switching memory cell comprises a volume of resistively switching material coupled to the transistor by a contact and wherein the contact and the word line are partially located vertically above an active area of the transistor.

3. The integrated circuit of claim 2, wherein the volume of resistively switching material is coupled to bit lines, the bit lines running perpendicular to word lines.

4. The integrated circuit of claim 1, wherein each active area of a transistor is coupled to a ground plate electrode, the ground plate electrode being formed as an N+ doped plate in the substrate.

5. The integrated circuit of claim 4, wherein the plurality of parallel insulating trenches and the plurality of perpendicular gate electrode trenches extend into the ground plate electrode.

6. The integrated circuit of claim 1, wherein the plurality of gate electrodes are formed from poly silicon.

7. The integrated circuit of claim 6, wherein the word line is formed from a layer of poly silicon and a layer of metal.

8. The integrated circuit of claim 7, wherein the metal is tungsten.

9. The integrated circuit of claim 1, wherein the plurality of resistively switching memory cells are phase change cells.

10. A memory component comprising the array of vertical transistors of claim 1.

11. An electronic system comprising the memory component of claim 10.

12. An integrated circuit comprising an array of vertical transistors formed in a substrate to select one of a plurality of resistively switching memory cells by selecting a word line and a bit line, the original surface of the substrate defining a horizontal reference plane, comprising:
a ground plate electrode in the substrate;
a plurality of parallel insulating trenches extending into the ground plate electrode and filled with an insulating material; and
a plurality of gate electrode trenches extending into the ground plate electrode and being perpendicular to the insulating trenches, the gate electrode trenches filled with a gate electrode material disrupted by the insulating material forming separate gate electrodes arranged below the reference plane;
the insulating trenches and the gate electrode trenches forming distinct active areas of transistors emerging from the substrate and coupled to the ground plate electrode, wherein two gate electrodes located at opposing sidewalls of an active area form a double gate electrode of a transistor; and
wherein a plurality of gate electrodes are coupled to a word line running perpendicular to the gate electrode trenches and above the reference plane.

13. The integrated circuit of claim 12, wherein a resistively switching memory cell comprises a volume of resistively switching material coupled to a transistor by a contact and wherein the contact and the word line are at least partially located vertically above the active area of the transistor.

14. The integrated circuit of claim 12, wherein the volumes of resistively switching material are coupled to bit lines, the bit lines running perpendicular to the word lines.

15. The integrated circuit of claim 12, wherein gate electrodes are formed from poly silicon.

16. The integrated circuit of claim 12, wherein the word lines are formed from a layer of poly silicon and a layer of metal.

17. The integrated circuit of claim 16, wherein the metal is tungsten.

18. The integrated circuit of claim 12, wherein the resistively switching memory cells are phase change cells.

19. The integrated circuit of claim 12, wherein the ground plate electrode in the substrate is formed by a layer of N+ doped substrate material.

20. A memory component comprising the array of vertical transistors of claim 12.

21. An electronic system comprising the memory component of claim 20.

22. A method of forming an integrated circuit comprising an array of transistors in a substrate for selecting one of a plurality of resistively switching memory cells, comprising:
forming a ground plate electrode in the substrate;
forming a plurality of parallel insulating trenches in the substrate;
forming a plurality of gate electrode trenches, the gate electrode trenches being perpendicular to the insulating trenches;
producing a liner of gate dielectric in the gate electrode trenches and filling the gate electrode trenches with a conducting gate electrode material; and
depositing a three layer stack of gate electrode material, word line material and insulating material and subsequently etching the three layer stack to form word lines running perpendicular to the gate electrode trenches, wherein the word lines are at least partially located vertically above active areas of transistors of the array of transistors.

23. The method of claim 22, wherein forming the ground plate electrode in the substrate comprises implanting N+ ions into a layer of the substrate.

24. The method of claim 22, wherein forming the plurality of parallel insulating trenches in the substrate comprises etching and filling stripes in the substrate.

25. A method of forming an integrated circuit comprising an array of transistors in a substrate for selecting one of a plurality of resistively switching memory cells, the original surface of the substrate defining a horizontal reference plane, comprising:
forming a ground plate electrode in the substrate by deeply implanting N+ ions into a layer of the substrate material;
forming a plurality of parallel insulating trenches in the substrate by etching and filling stripes in the substrate;
forming a plurality of gate electrode trenches, the gate electrode trenches being perpendicular to the insulating trenches, wherein the etching is selective to the insulation material of the insulating trenches, the insulating trenches and the gate electrode trenches thus producing active areas of transistors;
producing a liner of gate dielectric in the gate electrode trenches and filling the gate electrode trenches with a conducting gate electrode material;
depositing a three layer stack of gate electrode material, word line material and insulating material and subsequently etching the three-layer stack to form a word lines running perpendicular to the gate electrode trenches, the gate electrodes being coupled to word lines by the gate electrode material, wherein the word lines are at least partially located vertically above the active areas and wherein the etching extends into the gate electrode trenches;
producing a galvanically insulating layer at the sidewalls of the three-layer stack and in the gaps of the gate electrode trenches;
depositing a liner of insulating material and filling gaps between word lines with an insulating material;
forming contacts on the active areas to couple for providing a contact to a volume of resistively switching material by etching holes baring at least partially the top surface of the active areas and by filling these holes with a suitable conducting material; and
forming volumes of resistively switching material coupled to the contacts and forming bit lines coupled to the volumes of resistively switching material.

26. The method of claim 25, wherein a thick oxide layer and a layer of SiN are deposited on the surface before etching the trenches.

27. The method of claim 25, wherein insulation trenches extend into the ground plate electrode.

28. The method of claim 25, wherein the active areas produced by etching the insulation trenches and gate electrode trenches are thinned to produce active areas having a cross-sectional area of an elongated quadrangle.

29. The method of claim 25, wherein after etching the gate electrode trenches the bottom of the gate electrode trenches is N implanted to couple to the ground plate electrode.

30. The method of claim 25, wherein the gate electrode trenches are filled partially with gate electrode material and wherein the remaining opening to the reference surface is filled with a dielectric.

31. The method of claim 25, wherein before the three-layer stack is deposited well implants can be performed to configure the semiconductor transitions in the upper region of the transistors.

32. The method of claim 25, wherein an angled drain ion implant is performed after etching the word lines to implant ions into the sidewalls of an active area.

33. The method of claim 25, wherein after etching the holes baring at least partially the active areas and before filling the holes an epitaxial growth is performed in these holes to enlarge the contact interface area.

34. The method of claim 25, wherein the gate electrode material comprises poly silicon.

35. The method of claim 25, wherein the word line material comprises a metal.

36. The method of claim 35, wherein the metal is tungsten.

37. The method of claim 25, wherein the material to form the contacts for coupling to a volume of resistively switching material is a metal.

38. The method of claim 37, wherein the metal is tungsten.

39. An integrated circuit comprising an array of vertical transistors formed in a substrate to select one of a plurality of resistively switching memory cells by selecting a word line and a bit line, the original surface of the substrate defining a horizontal reference plane, comprising:
means for providing a plurality of parallel insulating trenches filled with an insulating material; and
means for providing a plurality of perpendicular gate electrode trenches filled with a gate electrode material, each perpendicular gate electrode trench of the plurality of perpendicular gate electrode trench means constructed between two consecutive parallel insulating trench means to form a plurality of gate electrodes arranged below the reference plane;
the insulating trench means and the gate electrode trench means forming distinct active areas of transistors of the array of vertical transistors in the substrate, wherein two gate electrodes located at opposing sidewalls of an active area form a double gate electrode of a transistor of the array of vertical transistors; and
means for coupling the plurality of gate electrodes to a word line running perpendicular to the plurality of perpendicular gate electrode trenches and above the reference plane.
